(19) United States
(12) Patent Application Publication
(10) Pub. No.: US 2022/0346233 A1
(43) Pub. Date: Oct. 27, 2022

(54) INTERPOSER ASSEMBLY AND ELECTRONIC COMPONENT

(71) Applicant: SHARP KABUSHIKI KAISHA, Sakai City (JP)

(72) Inventors: HIDENORI KUWAJIMA, Sakai City (JP); KENJI MAEDA, Sakai City (JP)

(21) Appl. No.: 17/722,818

(22) Filed: Apr. 18, 2022

(30) Foreign Application Priority Data
Apr. 22, 2021 (JP) 2021-072216

(51) Int. Cl. H05K 1/14; H05K 1/18; H05K 1/02

(52) U.S. Cl. CPC H05K 1/145; H05K 1/18; H05K 1/0203; H05K 2201/10378; H05K 2201/10015; H05K 2201/10022; H05K 2201/10159; H05K 2201/10537; H05K 7/20509

(57) ABSTRACT

An interposer assembly comprising:an interposer configured to connect a first circuit substrate and a second circuit substrate disposed facing the first circuit substrate with each other; and a penetrating member that extends through the interposer from a position on one side of the interposer to a position on the other side of the interposer, wherein the penetrating member has at least one of thermal conductivity and electrical conductivity.

### CROSS-REFERENCE TO RELATED APPLICATION

The present application claims priority from Japanese Application JP2021-072216, the content of which is hereby incorporated by reference into this application.

### BACKGROUND OF THE INVENTION

1. Field of the Invention

The present disclosure relates to an interposer assembly and an electronic component.

2. Description of the Related Art

As disclosed in JP 2017-188543 A, an electronic component in which a central processing unit (CPU) or a memory electrical element is mounted on a circuit substrate has been developed. Under such circumstances, recently, there has been an increasing need for an electronic component provided with an interposer that connects two circuit substrates that face each other so as to enclose a space between the two circuit substrates. In this electronic component, the interposer can electrically connect the two circuit substrates with each other.

### SUMMARY OF THE INVENTION

In the above-described electronic component, there is neither a heat release path nor an electrical conductive path from the space enclosed by the interposer between the two circuit substrates to a space on the outside. Because of this, an electrical element or an electrical wiring line is not disposed using the space enclosed by the interposer between the two circuit substrates. Thus, even in a configuration with the two circuit substrates, it is difficult to increase a degree of freedom of circuit design.

The present disclosure has been made in view of the problems described above. An object of the present disclosure is to provide an interposer assembly and an electronic component that can increase the degree of freedom of circuit design.

An interposer assembly of the present disclosure includes an interposer configured to connect a first circuit substrate and a second circuit substrate disposed facing the first circuit substrate with each other, and a penetrating member that extends through the interposer from a position on one side of the interposer to a position on the other side of the interposer, wherein the penetrating member has at least one of thermal conductivity and electrical conductivity.

An electronic component of the present disclosure includes a first circuit substrate, a second circuit substrate disposed facing the first circuit substrate, an interposer configured to connect the first circuit substrate and the second circuit substrate with each other and disposed surrounding a space between the first circuit substrate and the second circuit substrate, and a penetrating member that extends through the interposer from a space inside of the interposer and surrounded by the interposer to a space outside the space surrounded by the interposer, wherein the penetrating member has at least one of thermal conductivity and electrical conductivity.

### BRIEF DESCRIPTION OF THE DRAWINGS

FIG. 1 is a perspective view of an interposer assembly according to a first embodiment.

FIG. 2 is a lateral cross-sectional view of the interposer assembly according to the first embodiment and is a cross- sectional view taken along line II-II in FIG. 1.

FIG. 3 is a vertical cross-sectional view of an electronic component of the first embodiment.

FIG. 4 is a side view of the electronic component according to the first embodiment.

FIG. 5 is a lateral cross-sectional view of the electronic component according to the first embodiment and is a cross- sectional view taken along line V-IV in FIG. 3.

FIG. 6 is a lateral cross-sectional view of a modified example of the interposer assembly according to the first embodiment.

FIG. 7 is a perspective view of an interposer assembly according to a second embodiment.

FIG. 8 is a lateral cross-sectional view of the interposer assembly according to the second embodiment and is a cross- sectional view taken along line VIII-VIII in FIG. 7.

FIG. 9 is a vertical cross-sectional view of an electronic component of the second embodiment.

### DETAILED DESCRIPTION OF THE INVENTION

Hereinafter, an interposer assembly and an electronic component of the present disclosure will be described with reference to the drawings. Note that, in the drawings, identical or equivalent elements are given the same reference signs, and redundant descriptions of the identical or equivalent elements are not repeated.

First Embodiment

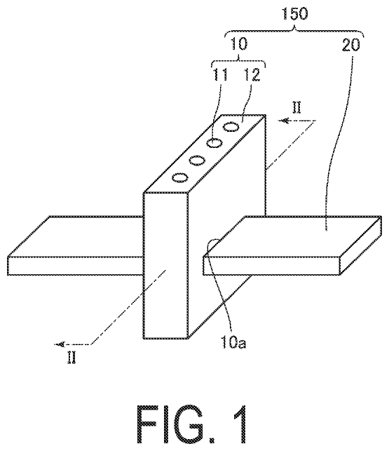

With reference to FIGS. 1 to 6, an interposer assembly and an electronic component of a first embodiment will be described.

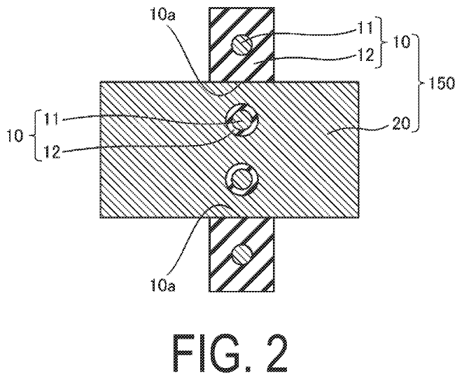

With reference to FIGS. 1 and 2, the interposer assembly of the first embodiment will be described. FIG. 1 is a perspective view of an interposer assembly 150 according to the present embodiment. FIG. 2 is a lateral cross-sectional view of the interposer assembly 150 of the present embodiment. As illustrated in FIGS. 1 and 2, the interposer assembly 150 includes an interposer 10 and a penetrating member 20. Note that a joint portion between the interposer 10 and the penetrating member 20 may have a structure similar to a structure of a rigid flexible substrate.

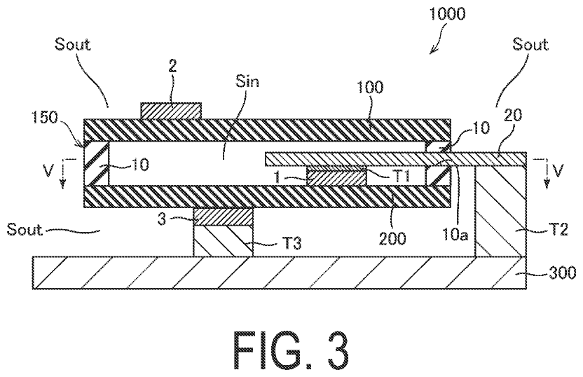

The interposer 10 may be physically connected to a circuit substrate 100 and a circuit substrate 200 described below (see FIG. 3). The interposer 10 includes a plurality of inter-substrate wiring lines 11 each made of a conductor such as copper, and an inter-substrate insulating portion 12 generally made of a material including a resin. The inter-substrate insulating portion 12 contains each of the plurality of inter- substrate wiring lines 11. Thus, the plurality of inter- substrate wiring lines 11 are insulated from each other by the inter-substrate insulating portion 12. The plurality of inter- substrate wiring lines 11 is capable of electrically connecting the circuit substrate 100 and the circuit substrate 200 described later with each other.

The penetrating member 20 is a plate-like member. The penetrating member 20 extends through the interposer 10 from a position on one side of the interposer 10 to a position on the other side of the interposer 10. Specifically, the penetrating member 20 is a plate-like member inserted through a through-hole 10a that extends from one main surface toward the other main surface of the interposer 10, which is like a wall. The penetrating member 20 of the present embodiment is made of copper having a thermal conductivity of 403 W/m·K. However, the penetrating member 20 may be made of a graphite sheet.

The penetrating member 20 has electrical conductivity in addition to thermal conductivity. Thus, the penetrating member 20 extends through the inter-substrate insulating portion 12 so as to be electrically insulated from the plurality of inter-substrate wiring lines 11 due to the inter-substrate insulating portion 12. Accordingly, the penetrating member 20 can be provided without disturbing the function of the inter- substrate wiring lines 11. As a result, the degree of freedom of circuit design of, for example, electrical elements (not illustrated) such as a central processing unit (CPU), a memory, a capacitor, or a resistor mounted on the circuit substrate 100 and the circuit substrate 200, or electrical wiring lines (not illustrated) can be increased. Note that the penetrating member 20 of the present embodiment need not have electrical conductivity provided that the penetrating member 20 has thermal conductivity.

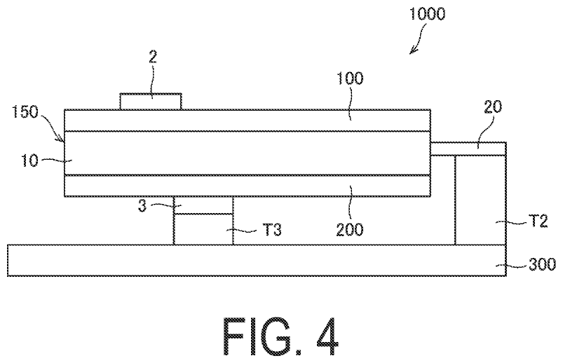

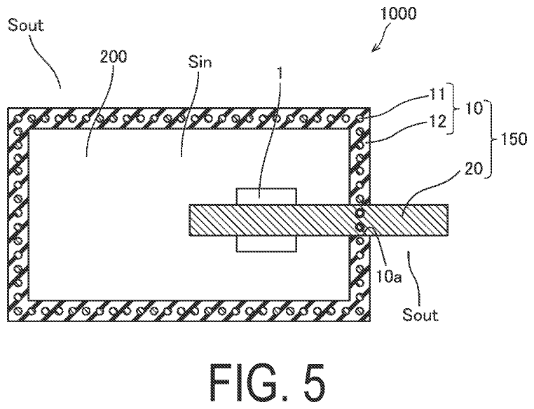

With reference to FIGS. 3 to 5, the electronic component of the first embodiment will be described. FIG. 3 is a vertical cross-sectional view of an electronic component 1000 of the present embodiment. FIG. 4 is a side view of the electronic component 1000 according to the present embodiment. FIG. 5 is a lateral cross-sectional view of the electronic component 1000 of the present embodiment.

As can be seen from FIGS. 3 and 4, the electronic component 1000 includes the circuit substrate 100, the circuit substrate 200, a heat source component 1, a heat source component 2, a heat source component 3, the interposer assembly 150, and a heat-transferred member 300.

The circuit substrate 100 is a flat plate made of a resin and is a wiring line substrate with electrical wiring lines (not illustrated) printed on both main surfaces of the flat plate. The circuit substrate 200 is also a flat plate made of a resin and is a wiring line substrate with electrical wiring lines (not illustrated) printed on both main surfaces of the flat plate. The circuit substrate 100 and the circuit substrate 200 are disposed so as to face each other across the interposer 10. The interposer 10 is physically connected to each of the circuit substrate 100 and the circuit substrate 200.

As illustrated in FIG. 5, the interposer 10 surrounds a space Sin between the circuit substrate 100 and the circuit substrate 200. Furthermore, the interposer 10 physically connects the circuit substrate 100 and the circuit substrate 200 with each other, thus electrically connecting the circuit substrate 100 and the circuit substrate 200 with each other.

The heat source component 1 is provided in the space Sin between the circuit substrate 100 and the circuit substrate 200. More precisely, the heat source component 1 is provided in the space Sin that is enclosed by the circuit substrate 100, the circuit substrate 200, and the interposer 10. The heat source component 1 is mounted on the circuit substrate 200 and is electrically connected to the electrical wiring lines printed on an inner main surface of the circuit substrate 200.

The heat source component 2 is mounted on an outer main surface of the circuit substrate 100 and is electrically connected to the electrical wiring line printed on the outer main surface. Thus, the heat source component 2 is provided in a space Sout outside the space Sin that is enclosed by the circuit substrate 100, the circuit substrate 200, and the interposer 10.

The heat source component 3 is mounted on an outer main surface of the circuit substrate 200 and is electrically connected to the electrical wiring lines printed on the outer main surface. Thus, the heat source component 3 is provided in the space Sout outside the space Sin that is enclosed by the circuit substrate 100, the circuit substrate 200, and the interposer 10.

Each of the heat source component 1, the heat source component 2, and the heat source component 3 is an electrical element that generates heat when a CPU or a memory, or the like is operated.

As can be seen from FIGS. 3 and 5, the interposer assembly 150 in the electronic component 1000 includes the interposer 10 and the penetrating member 20.

As can be seen from FIG. 5, the interposer 10 may be a frame member having a rectangular shape in plan view. However, the shape of the interposer 10 is not limited, and the interposer 10 may be a frame member having a polygonal shape, a circular shape, or an oval shape. Furthermore, the frame member need not be formed by one interposer 10.

For example, the frame member having a rectangular shape may be configured by connecting four interposers 10 each constituting a wall having a flat plate shape. Furthermore, the frame member having a rectangular shape may be formed by connecting end portions of two interposers 10 each having an L- shape. Furthermore, the frame member having a circular shape may be formed by connecting end portions of two interposers 10 each having a semicircular shape.

The penetrating member 20 extends from the space Sin inside of the interposes 10 and surrounded by the interposers 10 to the space Sout outside the space Sin surrounded by the interposers 10. The penetrating member 20 is indirectly connected to the heat source component 1 via a thermally- conductive material T1 referred to as a thermal interface material (TIM). Thus, the penetrating member 20 conducts heat generated by the heat source component 1 from an inner portion of the penetrating member 20 present in the space Sin inside of the interposers 10 to an outer portion of the penetrating member 20 present in the space Sout outside of the interposers 10. However, the penetrating member 20 may be directly connected to the heat source component 1.

The heat-transferred member 300 is a member referred to as sheet metal, and is a member made of stainless steel or aluminum. The heat-transferred member 300 is indirectly connected to the penetrating member 20 so as to indirectly transfer heat from the penetrating member 20 via a thermally- conductive member T2. However, the heat-transferred member 300 may be directly connected to the penetrating member 20.

According to the above configuration, the heat generated by the heat source component 1 is transferred to the heat-transferred member 300 via the thermally-conductive member T1, the penetrating member 20, and the thermally-conductive member T2. Thus, even when the heat source component 1 is provided in the space Sin enclosed by the circuit substrate 100, the circuit substrate 200, and the interposers 10, heat can escape from the space Sin to the outside of the space Sin. Thus, since the temperature of the heat source component 1 can be effectively reduced by the configuration described above, an electrical element that generates high heat and could not be disposed when used with an electronic component that does not have the configuration described above can be disposed at the position of the heat source component 1. Thus, the degree of freedom of circuit design of the electronic component 1000 can be increased.

In the present embodiment, the thermally-conductive member T1 is a thermally-conductive material made of a thermally-conductive sheet or a grease-like or gel-like substance that is sufficiently flexible and discharges air between the heat source component 1 and the penetrating member 20. On the other hand, the thermally-conductive member T2 is made of a graphite sheet. However, the thermally-conductive member T1, the thermally-conductive member T2, and the penetrating member 20 may be formed of one member that is integrally molded.

The heat-transferred member 300 is indirectly connected to the heat source component 3 via the thermally-conductive material T3 so that heat is indirectly transferred from the heat source component 3. However, the heat-transferred member 300 may be directly connected to the heat source component 3. According to this configuration, the heat emitted by the heat source component 3 can also be released by utilizing the heat- transferred member 300 for releasing the heat emitted by the heat source component 1.

The thermally-conductive material T3 of the present embodiment is a thermally-conductive material made of a thermally-conductive sheet or a grease-like or gel-like substance that is sufficiently flexible and discharges air between the heat source component 3 and the heat-transferred member 300. However, the thermally-conductive material T3 may also be made of a thermally-conductive sheet such as a graphite sheet, similar to the thermally-conductive member T1 and the thermally-conductive member T2.

Note that the thermally-conductive member T2 preferably has thermal conductivity of two or more times the thermal conductivity of copper.

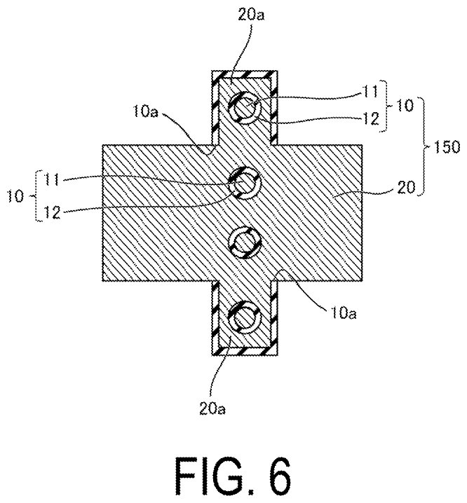

With reference to FIG. 6, a modified example of the interposer assembly 150 of the embodiment will be described. FIG. 6 is a lateral cross-sectional view of the modified example of the interposer assembly 150 according to the embodiment.

As illustrated in FIG. 6, the penetrating member 20 includes a protruding portion 20a that protrudes in a direction intersecting a penetration direction of the penetrating member 20 inside the interposer 10. According to this configuration, the heat dissipation effect of the heat source component 1 by the penetrating member 20 can be increased according to the size of the protruding portion 20a. The shape of the protruding portion 20a may be any shape such as a semicircular shape. The protruding portion 20a may be formed in the entirety of the interposer 10 having the frame shape in plan view. However, the protruding portion 20a is electrically insulated from the inter- substrate wiring lines 11 by the inter-substrate insulating portion 12.

Second Embodiment

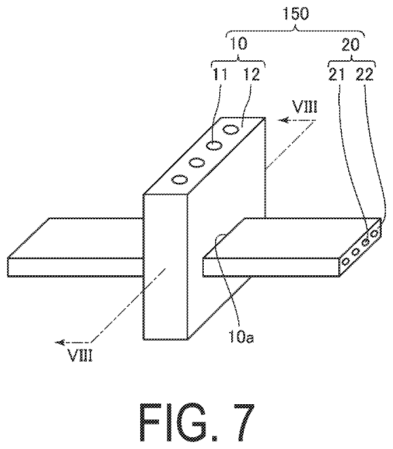

With reference to FIGS. 7 to 9, an interposer assembly and an electronic component of a second embodiment will be described. Note that the description of points similar to the first embodiment will not be repeated below. The interposer assembly 150 and the electronic component 1000 according to the present embodiment are different from the interposer assembly 150 and the electronic component 1000 of the first embodiment in the following points.

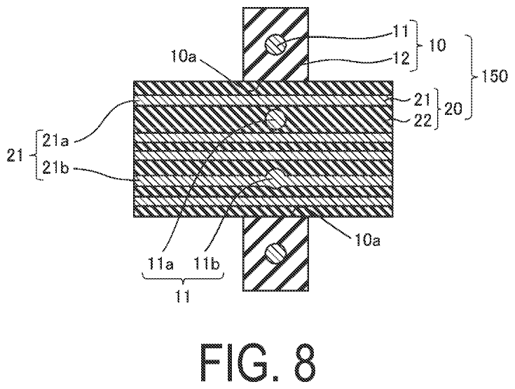

With reference to FIGS. 7 and 8, the interposer assembly 150 of the second embodiment will be described. FIG. 7 is a perspective view of the interposer assembly 150 according to the present embodiment. FIG. 8 is a lateral cross-sectional view of the interposer assembly 150 according to the second embodiment.

As illustrated in FIGS. 7 and 8, the penetrating member 20 includes a plurality of penetrating electrical wiring lines 21 and a penetrating insulating portion 22. The plurality of penetrating electrical wiring lines 21 extend through the interposer 10 from a position on one side of the interposer 10 to a position on the other side of the interposer 10. The penetrating insulating portion 22 extends through the interposer 10 from a position on one side of the interposer 10 to a position on the other side of the interposer 10 while separately containing each of the plurality of penetrating electrical wiring lines 21.

As illustrated in FIGS. 7 and 8, a penetrating electrical wiring line 21a of the plurality of penetrating electrical wiring lines 21 is electrically insulated from an inter-substrate wiring line lla by the penetrating insulating portion 22. According to this configuration, the penetrating electrical wiring line 21a can form an electrical path between one space of the interposer 10 and another space of the interposer 10.

Furthermore, a penetrating electrical wiring line 21b of the plurality of penetrating electrical wiring lines 21 is electrically connected to an inter-substrate wiring line 11b. According to this configuration, an electrical element connected to the inter-substrate wiring line llb and an electrical element connected to the penetrating electrical wiring line 21 can be electrically connected to each other. As a result, the degree of freedom of circuit design can be increased.

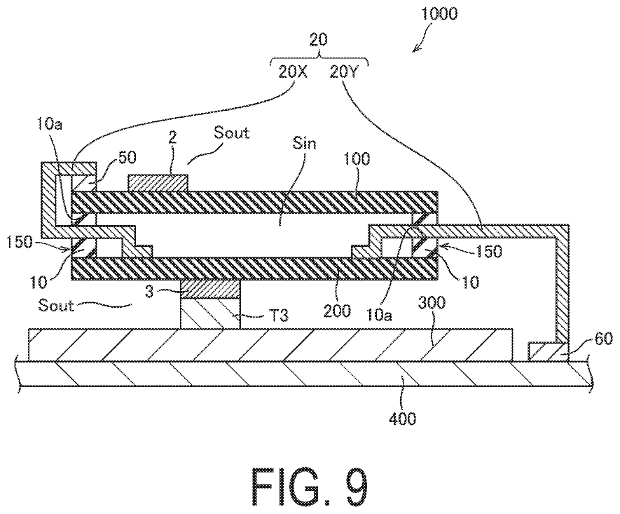

With reference to FIG. 9, the electronic component of the present embodiment will be described. FIG. 9 is a vertical cross-sectional view of the electronic component 1000 of the present embodiment.

The penetrating member 20 includes a penetrating member 20X and a penetrating member 20Y. Each of the penetrating member 20X and the penetrating member 20Y includes the plurality of penetrating electrical wiring lines 21 and the penetrating insulating portion 22, as illustrated in FIG. 8.

The plurality of penetrating electrical wiring lines 21 according to the present embodiment are, for example, copper wires and thus have electrical conductivity. Because of this, the penetrating insulating portion 22 extends from the space Sin inside of the interposer 10 to the space Sout outside of the interposer 10, while containing the plurality of penetrating electrical wiring lines 21. The penetrating insulating portion 22 insulates the plurality of penetrating electrical wiring lines 21 from each other.

According to the plurality of penetrating electrical wiring lines 21 of the present embodiment, an electric path is formed between the space Sin inside of the interposer 10 and the space Sout outside of the interposer 10. Thus, in a case where an electrical element or an electrical wiring line is provided in the space Sin inside of the interposer 10, the electrical element or the electrical wiring line and an electrical element or an electrical wiring line (not illustrated) provided in the space Sout outside of the interposer 10 can be electrically connected with each other. Specifically, a connector 50 on the circuit substrate 100 and the electrical wiring line formed in the space Sin inside of the interposer 10, such as an electrical wiring line on the main surface inside the circuit substrate 200, can be electrically connected with each other via the penetrating member 20X.

Furthermore, a connector 60 provided on an external member 400 to which the electronic component 1000 is mounted and the electrical wiring line (not illustrated) formed in the space Sin inside of the interposer 10 can be electrically connected with each other via the penetrating member 20Y. As a result, the degree of freedom of circuit substrate design can be increased.

Note that, as the external member 400, for example, a component of an electronic device such as a liquid crystal display (LCD) or an organic light emitting diode (OLED) may be used. Note that the electronic component 1000 of the present embodiment is provided, for example, on an inner surface of a housing.

Note that, in FIG. 9, although an electrical element such as a CPU is not drawn in the space Sin inside of the interposer 10, the electrical element may be provided in the space Sin. In this case, an electrical element provided in the space Sin and an electrical element provided in the space Sout of the outside may be electrically connected with each other via the penetrating electrical wiring line 21a in the penetrating member 20X or the penetrating member 20Y.

While there have been described what are at present considered to be certain embodiments of the invention, it will be understood that various modifications may be made thereto, and it is intended that the appended claim cover all such modifications as fall within the true spirit and scope of the invention.

What is claimd is:

1. An interposer assembly comprising:
an interposer configured to connect a first circuit substrate and a second circuit substrate disposed facing the first circuit substrate with each other; and
a penetrating member that extends through the interposer from a position on one side of the interposer to a position on the other side of the interposer,
wherein the penetrating member has at least one of thermal conductivity and electrical conductivity.

2. The interposer assembly according to claim 1,
wherein the interposer includes an inter-substrate wiring line configured to electrically connect the first circuit substrate and the second circuit substrate with each other, and an inter-substrate insulating portion containing the inter- substrate wiring line, and
the penetrating member has electrical conductivity in addition to thermal conductivity and extends through the inter- substrate insulating portion to be electrically insulated from the inter-substrate wiring line by the inter-substrate insulating portion.

3. The interposer assembly according to claim 1,
wherein the penetrating member includes a protruding portion that protrudes in a direction intersecting a penetration direction of the penetrating member inside the interposer.

4. The interposer assembly according to claim 1,
wherein the penetrating member includes
a penetrating electrical wiring line that extends through the interposer from a position on one side of the interposer to a position on the other side of the interposer, and
a penetrating insulating portion that extends through the interposer from a position on one side of the interposer to a position on the other side of the interposer while containing the penetrating electrical wiring line.

5. The interposer assembly according to claim 4,
wherein the interposer includes an inter-substrate wiring line configured to electrically connect the first circuit substrate and the second circuit substrate with each other and an inter-substrate insulating portion containing the inter- substrate wiring line, and
the penetrating electrical wiring line is electrically insulated from the inter-substrate wiring line by the penetrating insulating portion.

6. The interposer assembly according to claim 4,
wherein the interposer includes an inter-substrate wiring line configured to electrically connect the first circuit substrate and the second circuit substrate with each other and an inter-substrate insulating portion containing the inter- substrate wiring line, and
the penetrating electrical wiring line is electrically connected to the inter-substrate wiring line.

7. An electronic component comprising:
a first circuit substrate;
a second circuit substrate disposed facing the first circuit substrate;
an interposer configured to connect the first circuit substrate and the second circuit substrate with each other and disposed surrounding a space between the first circuit substrate and the second circuit substrate; and
a penetrating member that extends through the interposer from a space inside of the interposer and surrounded by the interposer to a space outside the space surrounded by the interposer,
wherein the penetrating member has at least one of thermal conductivity and electrical conductivity.

8. The electronic component according to claim 7, further comprising:
a first heat source component in the space between the first circuit substrate and the second circuit substrate,
wherein the penetrating member has thermal conductivity and is directly or indirectly connected to the first heat source component to conduct heat generated by the first heat source component from an inner portion of the penetrating member present in the space inside of the interposer to an outer portion of the penetrating member present in the space outside of the interposer.

9. The electronic component according to claim 8, further comprising:
a second heat source component mounted on an outer surface of one of the first circuit substrate and the second circuit substrate; and
a heat-transferred member directly or indirectly connected to the second heat source component, heat being directly or indirectly transferred from the second heat source component,
wherein the heat-transferred member is directly or indirectly connected also to the penetrating member, heat being directly or indirectly transferred also from the penetrating member.

10. The electronic component according to claim 7,
wherein the interposer includes an inter-substrate wiring line configured to electrically connect the first circuit substrate and the second circuit substrate with each other, and an inter-substrate insulating portion containing the inter- substrate wiring line, and
the penetrating member has electrical conductivity in addition to thermal conductivity and extends through the inter- substrate insulating portion to be electrically insulated from the inter-substrate wiring line by the inter-substrate insulating portion.

11. The electronic component according to claim 7,
wherein the penetrating member includes a protruding portion that protrudes in a direction intersecting a penetration direction of the penetrating member inside the interposer.

12. The electronic component according to claim 7,
wherein the penetrating member includes a penetrating electrical wiring line that extends through the interposer from a space inside of the interposer to a space outside of the interposer, and a penetrating insulating portion that extends through the interposer from the space inside of the interposer to the space outside of the interposer, while containing the penetrating electrical wiring line.

13. The electronic component according to claim 12,
wherein the interposer includes an inter-substrate wiring line electrically connecting the first circuit substrate and the second circuit substrate with each other, and an inter-substrate insulating portion containing the inter-substrate wiring line, and
the penetrating electrical wiring line is electrically insulated from the inter-substrate wiring line by the penetrating insulating portion.

14. The electronic component according to claim 12,
wherein the interposer includes an inter-substrate wiring line electrically connecting the first circuit substrate and the second circuit substrate with each other, and an inter-substrate insulating portion containing the inter-substrate wiring line, and
the penetrating electrical wiring line is electrically connected to the inter-substrate wiring line.
